(19) United States
(12) Patent Application Publication
(10) Pub. No.: US 2024/0321793 A1
(43) Pub. Date: Sep. 26, 2024

(54) CHIP PACKAGE ASSEMBLY WITH ENHANCED SOLDER PITCH

(71) Applicant: XILINX, INC., San Jose, CA (US)

(72) Inventors: Yun WU, San Jose, CA (US); Henley LIU, San Jose, CA (US); Myongseob KIM, Pleasanton, CA (US); Chris LEE, Taichung (TW); Cheang Whang CHANG, Mountain View, CA (US)

(21) Appl. No.: 18/125,660

(22) Filed: Mar. 23, 2023

(51) Int. Cl. H01L 23/00

(52) U.S. Cl. CPC H01L 24/06; H01L 24/05; H01L 24/16; H01L 2224/0401; H01L 2224/05555; H01L 2224/05557; H01L 2224/06132; H01L 2224/06177; H01L 2224/06179; H01L 2224/16227; H01L 2924/381; H01L 2924/3841

(57) ABSTRACT

An integrated circuit (IC) die includes a body having a dielectric layer and a plurality of contact pads formed on the dielectric layer. The IC die also includes a passivation layer disposed on the dielectric layer. The passivation layer has a plurality of openings exposing the plurality of contact pads. A plurality of inner under-bump-metallurgy (“UBM”) structures are disposed on a first portion of the plurality of openings, and a plurality of outer UBM structures are disposed on a second portion of the plurality of openings. The plurality of inner UBM structures have uniform spacing in a direction parallel to an edge of the body. The plurality of outer UBM structures are positioned around the plurality of inner UBM structures, and each of the plurality of outer UBM structures having a longitudinal axis directed toward a central area of the IC die.

### BACKGROUND

### Field of the Invention

Implementations described herein generally relate to chip packaging, and in particular, solder structures for improving solder pitch.

### Description of the Related Art

An increasing demand for electronic equipment that is smaller, lighter, and more compact has resulted in a concomitant demand for semiconductor packages that have smaller outlines and mounting areas or “footprints.” One response to this demand has been the development of the “flip-chip” method of attachment and connection of semiconductor chips or “dice” to substrates (e.g., PCBs or lead-frames). Flip-chip mounting involves the formation of bumped contacts (e.g., solder balls) on the active surface of the die, then inverting or “flipping” the die upside down and reflowing the bumped contacts (i.e., heating the bumped contacts to the melting point) to form solder joints fusing the bumped contacts to the corresponding pads on the substrate.

In flip-chip mounting and connection methods, reliability of solder connections is becoming an increasing concern of the electronics industry. One challenge is that the solder resist surrounding solder joints is susceptible to cracking, which during reflow of the solder joint, may permit the wicking of solder away from the solder joint, which may lead to cracking and poor performance. Additionally, as the number of solder connections on a chip package continues to increase, the pitch dimension between the solder connections chip packages continues to shrink.

Therefore, there is a need for improved solder pitch for an integrated circuit device.

### SUMMARY

An integrated circuit (“IC”) die includes a body having a dielectric layer and a plurality of contact pads formed on the dielectric layer. The IC die also includes a passivation layer disposed on the dielectric layer. The passivation layer has a plurality of openings exposing the plurality of contact pads. A plurality of inner under-bump-metallurgy (“UBM”) structures are disposed on a first portion of the plurality of openings, and a plurality of outer UBM structures are disposed on a second portion of the plurality of openings. The plurality of inner UBM structures have uniform spacing in a direction parallel to an edge of the body. The plurality of outer UBM structures are positioned around the plurality of inner UBM structures, and each of the plurality of outer UBM structures having a longitudinal axis directed toward a central area of the IC die.

In another embodiment, a chip package assembly includes an IC die and package substrate. The IC die has a plurality of inner bump structures uniformly spaced in a direction parallel to an edge of the body. The IC die also has a plurality of outer bump structures disposed around the plurality of inner bump structures. Each of the plurality of outer UBM structures having a longitudinal axis directed toward a central area of the IC die. The package substrate has a plurality of solder pads. Each of the plurality of solder pads has a pad surface exposed through a layer of solder resist and is arranged to connect to a respective one of the plurality of inner bump structures or the plurality of outer bump structures via solder connections.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of an exemplary integrated circuit chip package assembly.

FIG. 2 is a partial sectional view of an exemplary solder connection of the chip package assembly of FIG. 1.

FIG. 3 is a schematic top view of an upper surface of an integrated circuit (IC) die of the chip package assembly of FIG. 1. FIG. 3 illustrates the arrangement of the under-bump-metallurgy (“UBM”) structures on the upper surface of IC die.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Embodiments of the disclosure provide an IC die having improved solder pitch. In one embodiment, an integrated circuit (IC) die includes a body having a dielectric layer and a plurality of contact pads formed on the dielectric layer. The IC die also includes a passivation layer disposed on the dielectric layer. The passivation layer has a plurality of openings exposing the plurality of contact pads. A plurality of inner under-bump-metallurgy (“UBM”) structures are disposed on a first group of the plurality of openings, and a plurality of outer UBM structures are disposed on a second group of the plurality of openings. The plurality of inner UBM structures have uniform spacing in a direction parallel to an edge of the body. The plurality of outer UBM structures are positioned around the plurality of inner UBM structures, and each of the plurality of outer UBM structures has a longitudinal axis directed toward a central area of the IC die. This improved arrangement of the orientation of the outer UBM structures enhances the reliability of solder connections while the different orientation of the inner UBM structures enables tight pitch of the inner UBM structures without detrimentally increasing the potential for bridging between adjacent solder connections.

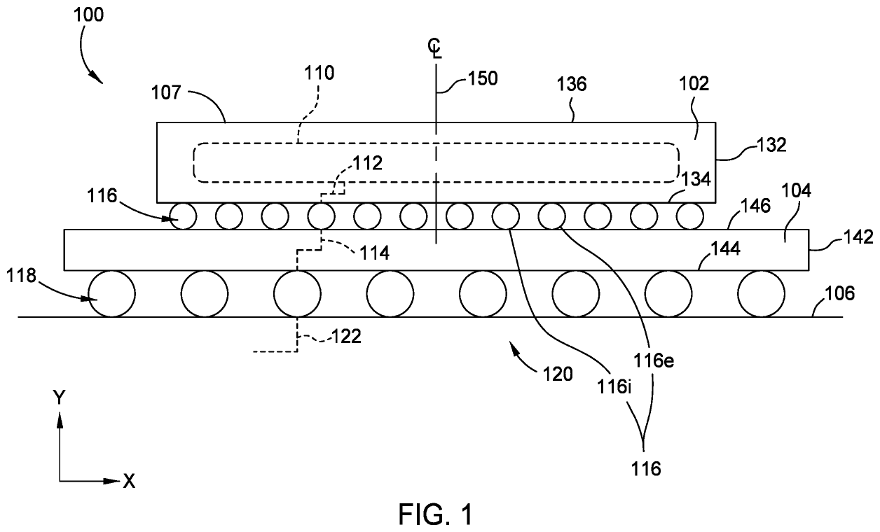

Turning now to FIG. 1, a schematic sectional view of an exemplary integrated circuit chip package assembly 100 having enhanced pitch for solder connections 116. The enhanced pitch of the solder connections 116 is enabled by uniformly spacing the outer solder connections 116e in a direction parallel to an edge of the body and positioning the plurality of outer UBM structures around the plurality of inner UBM structures. Each of the plurality of outer UBM structures have a longitudinal axis directed toward a central area of the IC die. Although the solder connections 116 are illustrated and described as joining an IC die and a package substrate, the arrangement of the outer solder connections 116e and inner solder connections 116i may be utilized to enhance solder connections between other components.

The chip package assembly 100 includes at least one integrated circuit (IC) die 102 mounted to a package substrate 104. Although one IC die 102 is shown mounted to the package substrate 104 in FIG. 1, one or more additional IC dies may be stacked directly on the IC die 102 and/or directly on the package substrate 104 laterally adjacent the IC die 102.

The IC die 102 may be, but are not limited to, programmable logic devices, such as field programmable gate arrays (FPGA), memory devices, such as high band-width memory (HBM), optical devices, processors, application-specific integrated circuit (ASIC), or other solid state, logic or memory structures. The IC die 102 may optionally include optical devices such as photo-detectors, lasers, optical sources, and the like.

The IC die 102 has a body 107 that includes a top surface 136, a bottom surface 134 and sides 132. Functional circuitry 110 resides in the body 107 of the IC die 102 and is connected to inputs and outputs residing on the bottom surface 134 of the IC die 102 by routing 112.

The package substrate 104 has a body that includes a top surface 146, a bottom surface 144, and sides 142. Routing 114 formed through the body of the package substrate 104 is connected to inputs and outputs residing on the top and bottom surfaces 146, 144 of the package substrate 104.

The solder connections 116 mechanically and electrically secure the IC die 102 to the package substrate 104. For example, the solder connections 116 mechanically couple the top surface 146 of the package substrate 104 to the bottom surface 134 of the IC die 102, while also electrically connecting the routings 112 formed in the IC die 102 with the routings 114 formed in the package substrate 104. The solder connections 116 include inner solder connections 116i that are located in an inner region of the IC die 102 and outer solder connections 116e that are located around the inner solder connections 116i.

The chip package assembly 100 may be mounted to a printed circuit board (PCB) 106 to form an electronic device 120. In this manner, the routing 114 of the package substrate 104 is coupled to the routing 122 of the PCB 106 via solder balls 118, or other suitable connection. In the example depicted in FIG. 1, the bottom surface 144 of the package substrate 104 is electrically and mechanically coupled to a top surface of the PCB 106 by the solder balls 118.

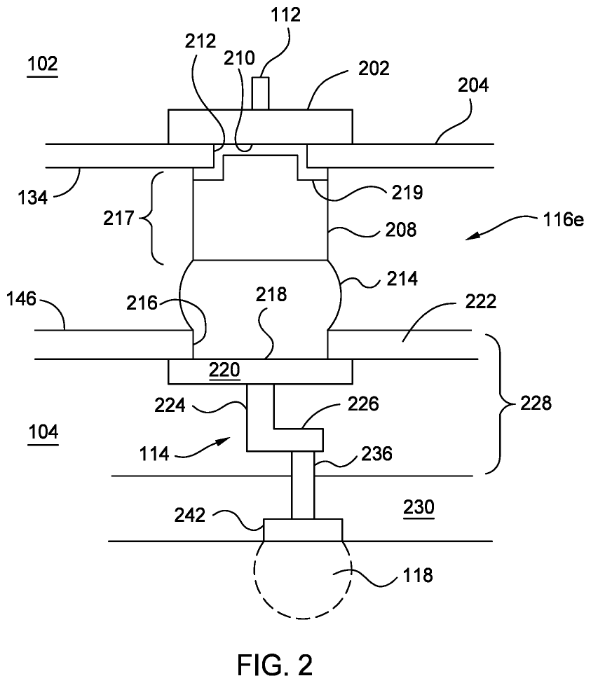

FIG. 2 is a partial sectional view of an exemplary outer solder connection 116e of the chip package assembly 100 detailing the components of the solder connection 116. It must be note the details of the outer solder connection 116e may also apply to the inner solder connections 116i. As shown, the IC die 102 has been flipped and engaged with the package substrate 104. The IC die 102 includes a contact pad 202 at which certain routing 112 of the IC die 102 terminates. In some embodiments, the contact pads 202 are formed and patterned in or on a top-level inter-layer dielectric layer. The contact pads 202 provide an electrical connection upon which a bump structure, such as a UBM structure or a copper pillar bump, may be formed for facilitating external electrical connections. The contact pads 202 may be formed of any suitable conductive materials, including one or more of copper (Cu), tungsten (W), aluminum (Al), AlCu alloys, silver (Al), or similar materials, for example. Although only one contact pad 202 is shown in FIG. 2, the number of contact pads 202 may be up to as many as space permits on the bottom surface 134 of the IC die 102.

A passivation layer 204 is disposed on the bottom surface 134 of the IC die 102. The passivation layer 204 includes an opening 212 through which an exposed surface 210 of the contact pad 202 is revealed. In at least one embodiment, the passivation layer 204 is formed of a non-organic material, such as un-doped silicate glass (USG), SIN, SiON, silicon oxide (SiO), or combinations thereof. The passivation layer 204 may be formed by any suitable method, such as chemical vapor deposition (CVD), physical vapor deposition (PVD), or the like. In other embodiments, the passivation layer 204 may be formed of a polymer layer, such as an epoxy, polyimide, benzocyclobutene (BCB), polybenzoxazole (PBO), or the like, although other relatively soft, often organic, dielectric materials can also be used. One of ordinary skill in the art will appreciate that a single layer of contact pads and a passivation layer are shown for illustrative purposes only. As such, other embodiments may include any number of contact pads and/or passivation layers.

A bump structure 217 is formed on the passivation layer 204 and electrically connected to the contact pad 202 through the opening 212. In some embodiments, the bump structure 217 includes an under-bump-metallurgy (UBM) structure 219 and a conductive pillar 208. The UBM structure 219 is formed over the surfaces of the passivation layer 204 and the exposed surface 210 of the contact pad 202. In some embodiments, the UBM structure 219 includes a diffusion barrier layer or a glue layer, which may comprise titanium (Ti), tantalum (Ta), titanium nitride (TiN), tantalum nitride (TaN), or the like and be formed by PVD or sputtering. The UBM structure 219 may further include a seed layer formed on the diffusion barrier layer by PVD or sputtering. The seed layer may be formed of copper (Cu) or copper alloys including Al, chromium (Cr), nickel (Ni), tin (Sn), gold (Ag), or combinations thereof. In at least one embodiment, the UBM structure 219 includes a Ti layer and a Cu seed layer.

The conductive pillar 208 is disposed on the UBM structure 219 and makes electrical connection with the exposed surface 210 of the contact pad 202. The pillar 208 is generally formed from a conductive metal, such as copper or other suitable metal. The pillar 208 and/or the UBM structure 219 may extend through the opening 212 and beyond the passivation layer 204 forming the bottom surface 134 of the IC die 102.

In one embodiment, the conductive pillar 208 includes a copper layer. The copper layer comprises pure elemental copper, copper containing unavoidable impurities, and/or copper alloys containing minor amounts of elements such as Ta, indium (In), SN, zinc (Zn), manganese (Mn), Cr, Ti, germanium (Ge), strontium (Sr), platinum (Pt), magnesium (Mg), aluminum (Al) or zirconium (Zr). The conductive pillar 208 may be formed by sputtering, printing, electroplating, electro-less plating, electrochemical deposition (ECD), molecular beam epitaxy (MBE), atomic layer deposition (ALD), and/or commonly used CVD methods. In one embodiment, the copper layer is formed by electro-chemical plating (ECP).

In some embodiments, the bump structure 217 has an elongated shape. Exemplary shapes of the elongated bump structure include a rectangle, a rectangle with at least one curved or rounded side, an oval, an ellipse or any other suitable elongated shape. In some embodiments, the bump structures 217 have a circular shape or a combination of circular and elongated shapes. In some embodiments, the dimension and shape of the conductive pillar 208 are substantially the same as those of the UBM structure 219. In some embodiments, the dimension and shape of the conductive pillar 208 are not exactly the same as those of the UBM structure 219. For example, the UBM structure 219 may be smaller than the dimension of the conductive pillar 208.

An optional conductive cap layer is formed on the conductive pillar 208. The conductive cap layer can be a metallization layer that may include nickel (Ni), Sb, tin-lead (SnPb), Au, Ag, palladium (Pd), In, Pt, NiPdAu, NiAu, or other similar materials or alloys. The conductive cap layer may be a multi-layered structure or a single-layered structure.

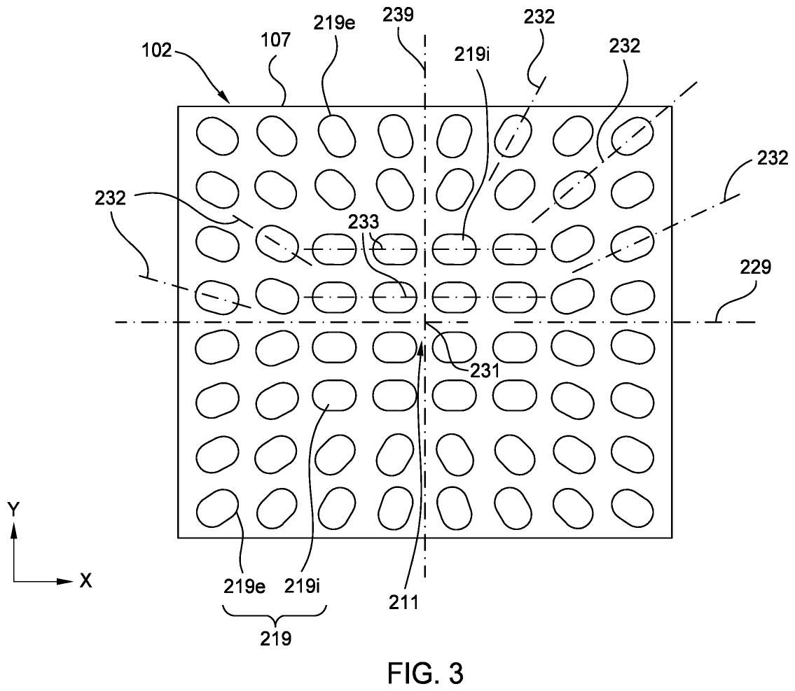

In some embodiments, the solder connections 116 securing the IC die 102 to the package substrate 104 are arranged to enhance the pitch of the solder connections 116. FIG. 3 shows an exemplary layout of a plurality of UBM structures 219 of the IC die 102. As shown, the UBM structures 219 are arranged in a predefined manner to ensure a sufficient pitch between the solder connections 116. The plurality of UBM structures 219 include a plurality of inner UBM structures 219i and a plurality of outer UBM structures 219e disposed around the inner UBM structures 219i. The inner UBM structures 219i and the outer UBM structures 219e may be the UBM structures 219 of FIG. 2. Although reference is made to the UBM structures 219, it must be noted the UBM structures 219 shown in FIG. 3 may represent the UBM structures 219, the pillar 208, or both (i.e., the bump structure 217). As noted above, the UBM structures 219 may have an elongated shape or other suitable shapes.

In FIG. 3, the inner UBM structures 219i are located in an inner region of the IC die 102. The outer UBM structures 219 are located in the periphery of the IC die 102 surrounding the inner UBM structures 219i. Each of the outer UBM structures 219e have an elongated shape which defines a longitudinal axis. The longitudinal axis has an orientation that is directed towards, or stated differently point to, a central area 211 of the IC die 102. As shown in FIG. 3, the longitudinal axes 232 of the outer UBM structures 219e are directed toward a central area 211 of the IC die 102. In some examples, the longitudinal axes 232 of the outer UBM structures 219e located to the left and right of the IC die 102 and near a horizontal axis 229 form a smaller angle with the horizontal axis 229 than the outer UBM structures 219e located near the corners of the IC die 102. The horizontal axis 229 may be a centerline that bifurcates the IC die 102 in the Y-axis. A vertical axis 239 may be a centerline that bifurcates the IC die 102 in the X-axis. The center 231 of the IC die 102 is the intersection between the horizontal axis 229 and the vertical axis 239. In one example, the longitudinal axes 232 of the outer UBM structures 219e located to the left and right of the IC die 102 and near a horizontal axis 229 form an angle of ±30 degrees with the horizontal axis 229, and the outer UBM structures 219e located near the corners form an angle from 30 degrees to 60 degrees with the horizontal axis 229. The outer UBM structures 219e located near the upper and lower portions of the IC die 102 form an angle closer to perpendicular with respect to the horizontal axis 229, such as from 60 degrees to 120 degrees with the horizontal axis 229. In FIG. 3, the outer UBM structures 219e are arranged in a plurality of rows and a plurality of columns. The longitudinal axes 232 of at least two outer UBM structures 219e positioned in the same row form different angles with the horizontal axis 229. Also, the longitudinal axes 232 of at least two outer UBM structures 219e positioned in the same column form different angles with the horizontal axis 229. In some embodiments, the longitudinal axes 232 of the outer UBM structures 219e are aligned in a radial or substantially radial direction with respect to the center 231 of the IC die 102. In some examples, some or all of the longitudinal axes 232 of outer UBM structures 219e pass through the center of the IC die 102 (the intersection of the horizontal axis 229 and the vertical axis 239). In other examples, none of the longitudinal axes 232 of outer UBM structures 219e pass through the center of the IC die 102.

In some embodiments, the inner UBM structures 219i are uniformly spaced on the IC die 102. For example, the inner UBM structures 219i may have uniform spacing (i.e., pitch) in a direction parallel to an edge of the IC die 102. In FIG. 3, the inner UBM structures 219i are arranged in uniform columns and uniform rows. The rows of inner UBM structures 219i are aligned in a direction parallel to the edge of the body 107 of the IC die 102. The plurality of the inner UBM structures 219i may include elongated UBM structures, circular UBM structures, or both. In this example, the inner UBM structures 219i are centrally positioned relative to the central area 211. In some embodiments, it is contemplated the inner UBM structures 219i are located in an inner region of the IC die 102, but not centrally positioned. For example, with reference to FIG. 3, the inner UBM structures 219i may comprise only the two rows of uniformly spaced inner UBM structures 219i located above the horizontal axis 229. In this example, the two rows of inner UBM structures 219i located below the horizontal axis 229 would instead be outer UBM structures 219e having a longitudinal axis pointed toward the central area 211. In some embodiments, the plurality of inner UBM structures are arranged to form at least two adjacent rows and to form at least two adjacent columns (e.g., 2×2, 2×3, 3×3 arrangements) that are uniformly spaced on the body of the IC die 102.

In some embodiments, the inner UBM structures 219i having an elongated shape are positioned so their longitudinal axes 233 share a common direction. In the example shown in FIG. 3, in addition to being uniformly spaced, the longitudinal axes 233 of the inner UBM structures 219i are aligned in a common direction with the edge of the body 107, which in this example is parallel to the horizontal axis 229. The inner UBM structures 219i in the same row are co-axially aligned, and the inner UBM structures 219i in adjacent rows are aligned in parallel. In some examples, one or more of the inner UBM structures 219i may form a small angle, such as ±5 degrees or ±3 degrees, with the common direction (e.g., horizontal axis 229 or vertical axis 239) of the inner UBM structures 219i. While the arrangement of the inner UBM structures 219i are discussed as being horizontally aligned, it is contemplated the inner UBM structures 219i may be arranged with respect to a vertical axis 239 that is perpendicular to the horizontal axis 229. For example, the longitudinal axes 233 of the inner UBM structures 219i may be directionally aligned with respect to the vertical axis. In some examples, one or more of the inner UBM structures 219i may form a small angle, such as ±5 degrees, ±3 degrees, or ±1 degree, with the vertical axis that is perpendicular to the horizontal axis 229.

Accordingly, it is believed the combined arrangement of the outer UBM structures 219e longitudinally aligned with a central area 211 of the IC die 102 and the inner UBM structures 219i uniformly spaced in a direction parallel to an edge of the IC die 102 enhances the pitch of the UBM structures 219. In this respect, the combined arrangement of the outer UBM structures 219e and the inner UBM structures 219i advantageously reduces the potential for bridging between adjacent solder connections 116. Accordingly, a more robust and reliable electrical connection is realized.

Referring back to FIG. 2, the bump structure 217, including the UBM 219 and the pillar 208 electrically connects the IC die 102 to the substrate 104. The package substrate 104 includes at least a built-up layer 228 formed on a core 230. Optionally, a second built-up layer may be formed on the opposite side of the core 230.

The built-up layer 228 extends from the core 230 and terminates to define the top surface of the package substrate 104. The top surface is generally defined by a layer of solder resist 222. The solder resist 222 includes an opening 216 through which an exposed surface 218 of the solder pad 220 is revealed. A solder ball 214 is disposed on and makes electrical connection with the exposed surface 218. The solder ball 214 extends through the opening 216 and beyond the solder resist 222. The solder ball 214, after mounting of the IC die 102 to the package substrate 104 and reflow, makes mechanical and electrical connection between the solder pad 220 and pillar 208, thus connecting the functional circuitry 110 of the IC die 102 with the electrical routing 114 of the package substrate 104.

The built-up layer 228 also includes the routing 114 of the package substrate 104. In the package substrate 104, the routing 114 of the built-up layer 228 is fabricated using conductive vias 224 and conductive lines 226. One of the conductive vias or lines 224, 226 terminate at the solder pad 220. One of the conductive vias or lines 224, 226 also terminate at feed through 236 formed through the core 230. The core 230 provides the structural rigidity to the package substrate 104 and may be fabricated from silicon, ceramic, glass reinforced plastic or other suitable material. Additional conductive vias or lines may connect the feed through 236 to the contact pad 242, which is utilized to connect with the solder ball 118 (shown in phantom in FIG. 2).

In addition to the claim recited below, additional examples of the disclosure may be recited as follows.

An integrated circuit (“IC”) die includes a body having a dielectric layer and a plurality of contact pads formed on the dielectric layer. The IC die also includes a passivation layer disposed on the dielectric layer. The passivation layer has a plurality of openings exposing the plurality of contact pads. A plurality of inner under-bump-metallurgy (“UBM”) structures are disposed on a first portion of the plurality of openings, and a plurality of outer UBM structures are disposed on a second portion of the plurality of openings. The plurality of inner UBM structures have uniform spacing in a direction parallel to an edge of the body. The plurality of outer UBM structures are positioned around the plurality of inner UBM structures, and each of the plurality of outer UBM structures having a longitudinal axis directed toward a central area of the IC die.

In some embodiments, the plurality of inner UBM structures includes at least two inner UBM structures having an elongated shape and a longitudinal axis aligned in the direction parallel to the edge of the body.

In some embodiments, the longitudinal axes of the at least two inner UBM structures and the edge of the body are aligned in a direction parallel to a horizontal axis bifurcating the body along a Y-axis.

In some embodiments, the longitudinal axes of the at least two inner UBM structures and the edge of the body are aligned in a direction parallel to a vertical axis bifurcating the body along an X-axis.

In some embodiments, the plurality of inner UBM structures includes at least two inner UBM structures having a circular shape.

In another embodiment, a chip package assembly includes an IC die and package substrate. The IC die has a plurality of inner bump structures uniformly spaced in a direction parallel to an edge of the body. The IC die also has a plurality of outer bump structures disposed around the plurality of inner bump structures. Each of the plurality of outer UBM structures having a longitudinal axis directed toward a central area of the IC die. The package substrate has a plurality of solder pads. Each of the plurality of solder pads has a pad surface exposed through a layer of solder resist and is arranged to connect to a respective one of the plurality of inner bump structures or the plurality of outer bump structures via solder connections.

While the foregoing is directed to embodiments of the present invention, other and further embodiments of the invention may be devised without departing from the basic scope thereof, and the scope thereof is determined by the claims that follow.

What is claimed is:

1. An integrated circuit (IC) die, comprising:
a body having a dielectric layer;
a plurality of contact pads formed on the dielectric layer;
a passivation layer disposed on the dielectric layer, the passivation layer having a plurality of openings exposing the plurality of contact pads;
a plurality of inner under-bump-metallurgy (“UBM”) structures disposed on a first group of the plurality of openings, the plurality of inner UBM structures having uniform spacing in a direction parallel to an edge of the body; and
a plurality of outer UBM structures disposed on a second group of the plurality of openings, the plurality of outer UBM structures positioned around the plurality of inner UBM structures, and each of the plurality of outer UBM structures having a longitudinal axis directed toward a central area of the IC die.

2. The IC die of claim 1, wherein the plurality of inner UBM structures includes at least two inner UBM structures having an elongated shape and a longitudinal axis aligned in the direction parallel to the edge of the body.

3. The IC die of claim 2, wherein the longitudinal axes of the at least two inner UBM structures and the edge of the body are aligned in a direction parallel to a horizontal axis bifurcating the body along a Y-axis.

4. The IC die of claim 2, wherein the longitudinal axes of the at least two inner UBM structures and the edge of the body are aligned in a direction parallel to a vertical axis bifurcating the body along an X-axis.

5. The IC die of claim 2, wherein the plurality of inner UBM structures includes at least two inner UBM structures having a circular shape.

6. The IC die of claim 1, wherein the longitudinal axes of at least two or more of the plurality of outer UBM structures are not parallel.

7. The IC die of claim 6, wherein the at least two or more outer UBM structures are positioned in a same row.

8. The IC die of claim 1, wherein the longitudinal axes of the plurality of outer UBM structures are radially aligned with a center of the body of the IC die.

9. The IC die of claim 1, wherein the plurality of inner UBM structures are arranged to form at least two adjacent rows and to form at least two adjacent columns on the body of the IC die.

10. The IC die of claim 1, further comprising a pillar disposed on each of the plurality of inner UBM structures and the plurality of outer UBM structures.

11. The IC die of claim 10, wherein the pillar has substantially a same shape as the plurality of inner UBM structures.

12. The IC die of claim 1, wherein the plurality of inner UBM structures are centrally positioned on the body.

13. A chip package assembly comprising:
an integrated circuit (IC) die having:
a plurality of inner bump structures uniformly spaced in a direction parallel to an edge of the body; and
a plurality of outer bump structures disposed around the plurality of inner bump structures, each of the plurality of outer UBM structures having a longitudinal axis directed toward a central area of the IC die; and
a package substrate having a plurality of solder pads, each of the plurality of solder pads having a pad surface exposed through a layer of solder resist and is arranged to connect to a respective one of the plurality of inner bump structures or the plurality of outer bump structures via solder connections.

14. The assembly of claim 13, wherein the plurality of inner bump structures include at least two inner bump structures having an elongated shape and a longitudinal axis aligned in the direction parallel to the edge of the body.

15. The assembly of claim 14, wherein the longitudinal axes of the at least two inner bump structures and the edge of the body are aligned in a direction parallel to a horizontal axis bifurcating the body along a Y-axis.

16. The assembly of claim 13, wherein the longitudinal axes of at least two or more of the plurality of outer bump structures are not parallel.

17. The assembly of claim 16, wherein the at least two or more outer bump structures are positioned in a same row.

18. The assembly of claim 13, wherein the longitudinal axes of the plurality of outer bump structures are radially aligned with a center of the body of the IC die.

19. The assembly of claim 13, wherein the plurality of inner bump structures are arranged to form at least two adjacent rows and to form at least two adjacent columns on the body of the IC die.

20. The assembly of claim 13, wherein the plurality of inner bump structures include an under-bump-metallurgy (“UBM”) structure and a pillar disposed on the UBM structure.
